(19) United States
(12) Patent Application Publication
(10) Pub. No.: US 2025/0054872 A1
(43) Pub. Date: Feb. 13, 2025

(54) OVERLAY METROLOGY TARGET FOR DIE-TO-WAFER OVERLAY METROLOGY

(71) Applicant: KLA Corporation, Milpitas, CA (US)

(72) Inventors: Shlomo Eisenbach, Kfar Pines (IL); Ohad Bachar, Timrat (IL); Roie Volkovich, Hadera (IL); Oren Ben-nun, Kfar Baruch (IL); Avner Safrani, Misgav (IL)

(21) Appl. No.: 18/421,454

(22) Filed: Jan. 24, 2024

Related U.S. Application Data
(60) Provisional application No. 63/532,079, filed on Aug. 11, 2023.

(51) Int. Cl. H01L 23/544; G03F 7/00; G03F 9/00

(52) U.S. Cl. CPC H01L 23/544; G03F 7/70525; G03F 7/70633; G03F 7/706831; G03F 9/7076; G03F 9/708; G03F 9/7084; H01L 2223/54426

(57) ABSTRACT

A method includes identifying a printing location of a first set of alignment marks on a wafer outside a geometric shadow defined by a numerical aperture and a die height of a die. The method includes fabricating an overlay metrology target by printing the first set of alignment marks based on the identified print location and printing a second set of alignment marks on a surface of the die. The method includes identifying a metrology recipe including a set of measurement parameters, where the set of measurement parameters include at least a focal position of an objective lens. The focal position of the objective lens may be a predetermined distance below a top surface of the die defined by a maximal numerical aperture and the die height of the die. The method includes measuring overlay of the overlay metrology target in accordance with the identified metrology recipe.

### CROSS-REFERENCE TO RELATED APPLICATIONS

The present application claims the benefit under 35 U.S.C. § 119(e) of U.S. Provisional Application Ser. No. 63/532,079, filed Aug. 11, 2023, entitled AN EFFECTIVE TARGET DESIGN FOR DIE TO WAFER OVERLAY METROLOGY, naming Shlomo Eisenbach, Ohad Bachar, Roie Volkovich, Oren Ben-nun, and Avner Safrani, as inventors, which is incorporated herein by reference in the entirety.

### TECHNICAL FIELD

The present disclosure is related generally to overlay metrology and, more particularly, to an overlay metrology target for an overlay metrology system.

### BACKGROUND

In the semiconductor industry, modern chip devices may be made of stacked wafers and dies. Overlay targets (or alignment marks) are printed on the stacked wafers and dies in different locations for the purpose of overlay metrology and process control. Often, the overlay targets are printed on the wafer scribe line and on the corner of the die in a side-by-side (SBS) die-to-wafer overlay target design.

The SBS target design has the advantage of saving space on the wafer since the targets are printed on the scribe line. However, the scribe lines are often limited in width which limits the SBS target distance from the stacked die. In addition, as the dies stacked on the wafer have a large thickness, the walls of the dies block light from hitting the target and generate shadows that prevent accurate measurement. Placing the overlay target away from the edge of the scribe line may limit the density of the dies, which results in an ineffective die-to-wafer manufacturing process. In addition, such ineffective design results in an ineffective metrology process as each die mis-alignment must be measured separately.

Therefore, there is a need for a system and method for providing a target design that minimizes die shadowing and thereby allows effective, high density, high throughput die-to-wafer overlay metrology.

### SUMMARY

A method is disclosed, in accordance with one or more embodiments of the present disclosure. In embodiments, the method includes identifying a printing location of a first set of alignment marks on a wafer, where the first set of alignment marks are outside a geometric shadow defined by a numerical aperture and a die height of a die. In embodiments, the method includes fabricating an overlay metrology target by printing the first set of alignment marks on the wafer based on the identified print location and printing a second set of alignment marks on a surface of the die. In embodiments, the method includes identifying a metrology recipe including a set of measurement parameters, where the set of measurement parameters include at least a focal position of an objective lens, where the focal position of the objective lens is a predetermined distance below a top surface of the die, where the predetermined distance is defined by a maximal numerical aperture and the die height of the die. The method includes measuring overlay of the overlay metrology target including the first set of alignment marks on the surface of the wafer and the second set of alignment marks on the surface of the die in accordance with the identified metrology recipe.

An overlay metrology target is disclosed, in accordance with one or more embodiments of the present disclosure. In embodiment, the overlay metrology target includes a first set of alignment marks arranged on a surface of a wafer. In embodiment, the overlay metrology target includes a second set of alignment marks arranged on a surface of a die, where the first set of alignment marks arranged on the wafer are outside a geometric shadow defined by a numerical aperture and a height of the second set of alignment marks arranged on the surface of the die.

A control system is disclosed, in accordance with one or more embodiments of the present disclosure. In embodiment, the control system includes a controller configured to be communicatively coupled with an overlay metrology sub-system. In embodiments, the controller includes one or more processors configured to execute program instructions causing the one or more processors to: identify a printing location of a first set of alignment marks on a wafer, where the first set of alignment marks are outside a geometric shadow defined by a numerical aperture and a die height of a die; provide the selected printing location to a fabrication sub-system to fabricate an overlay metrology target by printing the first set of alignment marks on the wafer based on the identified print location and printing a second set of alignment marks on a surface of the die; determine a metrology recipe including a set of measurement parameters, where the set of measurement parameters include at least a focal position of an objective lens, where the focal position of the objective lens is a predetermined distance below a top surface of the die, where the predetermined distance is defined by a maximal numerical aperture and the die height of the die; and provide the determined metrology recipe to the overlay metrology sub-system to measure overlay of the overlay metrology target including the first set of alignment marks on the surface of the wafer and the second set of alignment marks on the surface of the die in accordance with the identified metrology recipe.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1 is a simplified block diagram of a system, in accordance with one or more embodiments of the present disclosure.

FIG. 2A is a top view of an overlay metrology target, in accordance with one or more embodiments of the present disclosure.

FIG. 2B is a side view of an overlay metrology target, in accordance with one or more embodiments of the present disclosure.

FIG. 2C is a top view of an overlay metrology target, in accordance with one or more embodiments of the present disclosure.

FIG. 2D is a top view of an overlay metrology target, in accordance with one or more embodiments of the present disclosure.

FIG. 2E is a top view of an overlay metrology target, in accordance with one or more embodiments of the present disclosure.

FIG. 2F is a top view of an overlay metrology target, in accordance with one or more embodiments of the present disclosure.

FIG. 2G is a side view of an overlay metrology target, in accordance with one or more embodiments of the present disclosure.

FIG. 3A is a top view of an overlay metrology target.

FIG. 3B is a side view of an overlay metrology target.

FIG. 4 is a flow chart depicting a method for fabricating and measuring an overlay metrology target, in accordance with one or more embodiments of the present disclosure.

FIG. 5 is a simplified model of die-to-wafer shadowing of an overlay metrology target, in accordance with one or more embodiments of the present disclosure.

FIG. 6A is simulation plot depicting die height validation, in accordance with one or more embodiments of the present disclosure.

FIG. 6B is simulation plot depicting die height validation, in accordance with one or more embodiments of the present disclosure.

FIG. 7A is simulation plot depicting die edge shadowing validation, in accordance with one or more embodiments of the present disclosure.

FIG. 7B is simulation plot depicting die edge shadowing validation, in accordance with one or more embodiments of the present disclosure.

FIG. 8 is a simplified model of a measurement position of an overlay metrology target, in accordance with one or more embodiments of the present disclosure.

FIG. 9 is simplified schematic of an overlay metrology sub-system, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to die-to-wafer overlay metrology using die-to-wafer overlay metrology targets. For example, the die-to-wafer targets may include a first set of alignment marks on a surface of the wafer and a second set of alignment marks on a surface of the die. The design of the die-to-wafer overlay target may be selected such that a print location of the first set of alignment marks on the wafer are outside a geometric shadow defined by at least one of the numerical aperture (NA), die thickness, or the die material. In this regard, a fabrication sub-system may fabricate the die-to-wafer overlay target based on the selected print location of the first set of alignment marks on the wafer, such that an accurate overlay measurement may be determined using an overlay metrology sub-system. Further, the overlay metrology sub-system may simultaneously measure the first set of alignment marks on the wafer and the second set of alignment marks on the die. For example, a metrology recipe may be identified where a focal position of an objective lens (i.e., predetermined distance below a top surface of the die) is selected such that simultaneously measurement may be achieved. The focal position of the objective lens may be defined based on at least a maximal numerical aperture and the die height of the die.

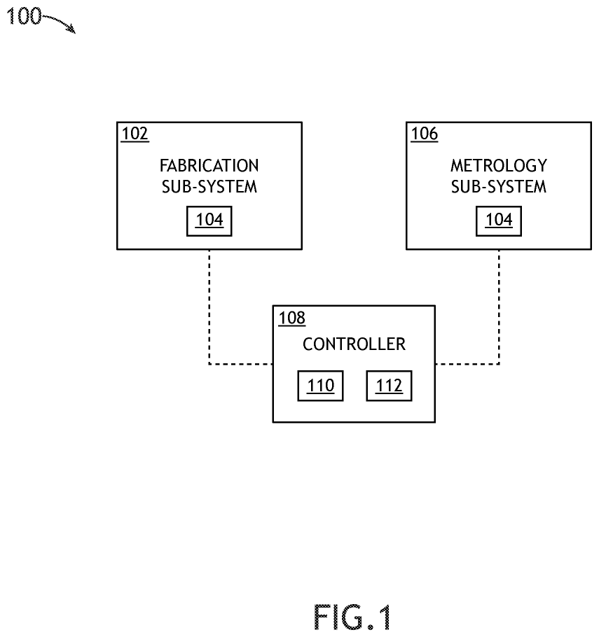

FIG. 1 illustrates a control system 100, in accordance with one or more embodiments of the present disclosure.

In embodiments, the control system 100 is configured to control a fabrication sub-system 102 configured to fabricate one or more overlay metrology targets 104. In embodiments, the control system 100 is configured to control a metrology sub-system 106 configured to determine die-to-wafer overlay of the fabricated one or more metrology targets 104. In embodiments, the control system 100 includes a controller 108 including one or more processors 110 and memory 112.

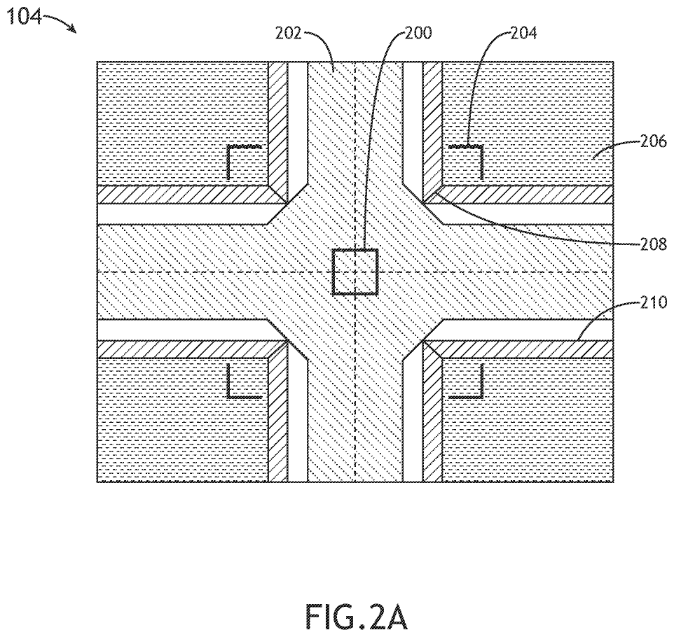

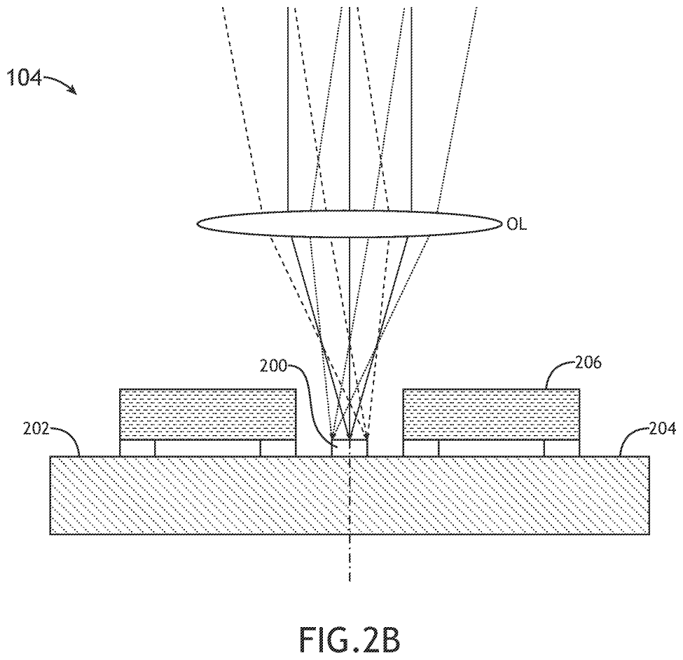

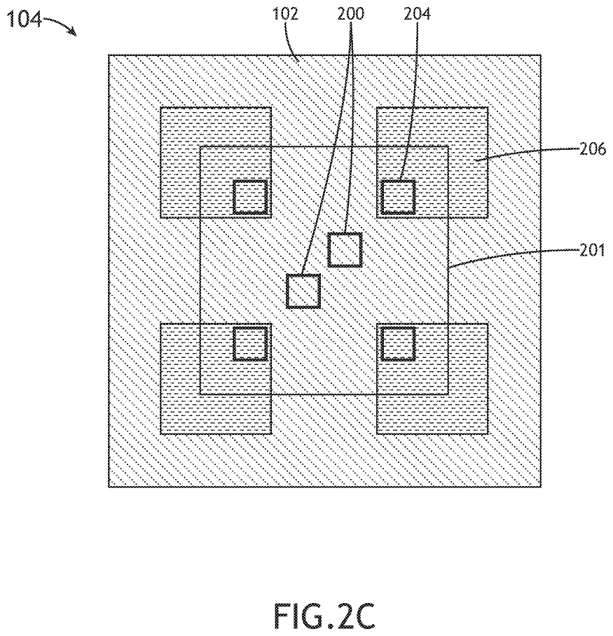

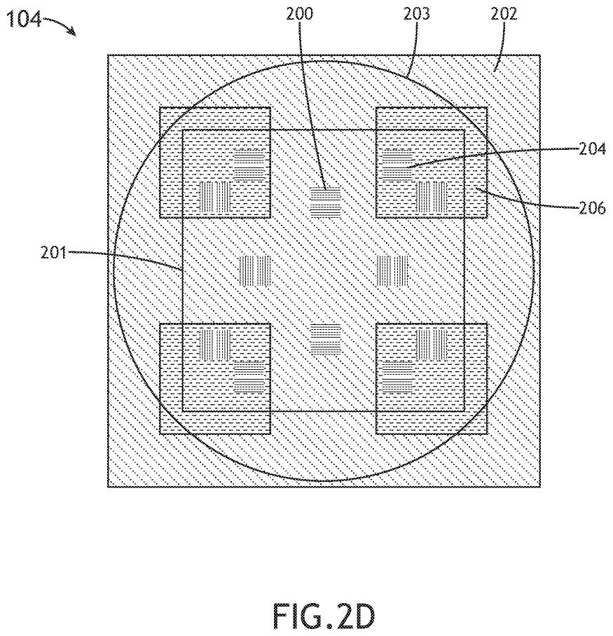

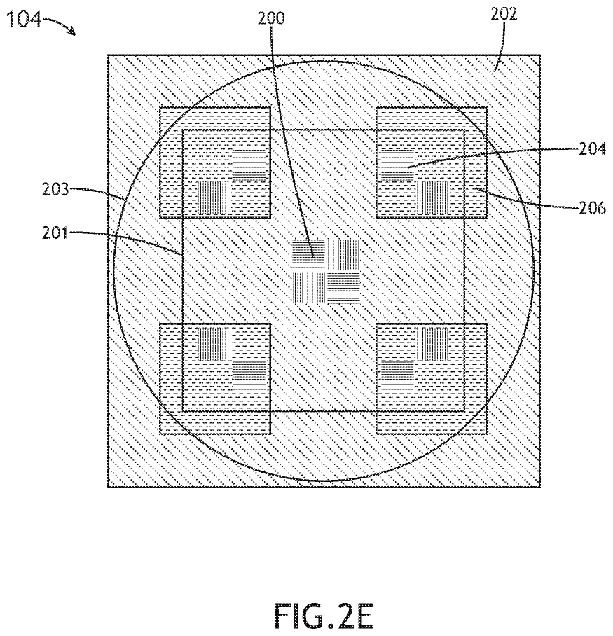

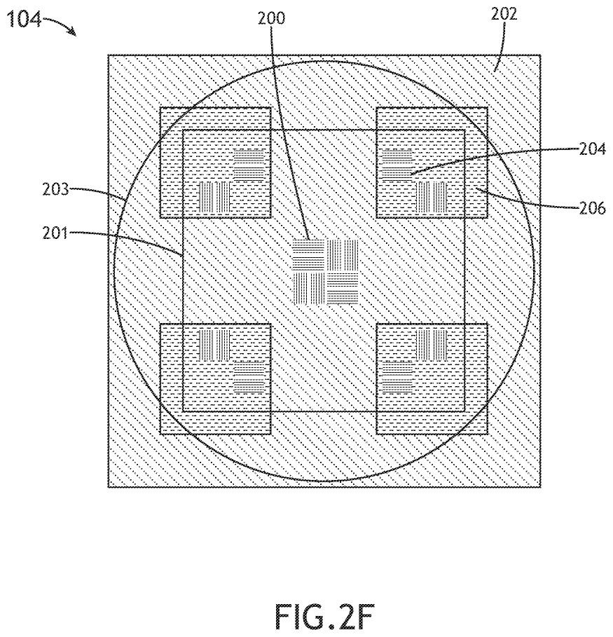

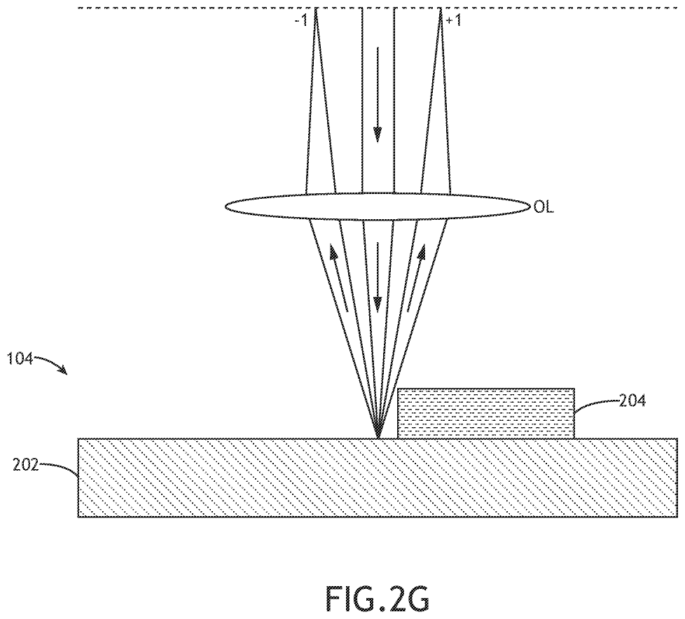

FIGS. 2A-2G illustrate an overlay metrology target 104, in accordance with one or more embodiments of the present disclosure.

In embodiments, the overlay metrology target 104 includes a die-to-wafer metrology target 104. For example, as shown in FIG. 2A, the overlay metrology target 104 may include a first set of alignment marks 200 on a surface of a wafer 202 and a second set of alignment marks 204 on a surface of a die 206.

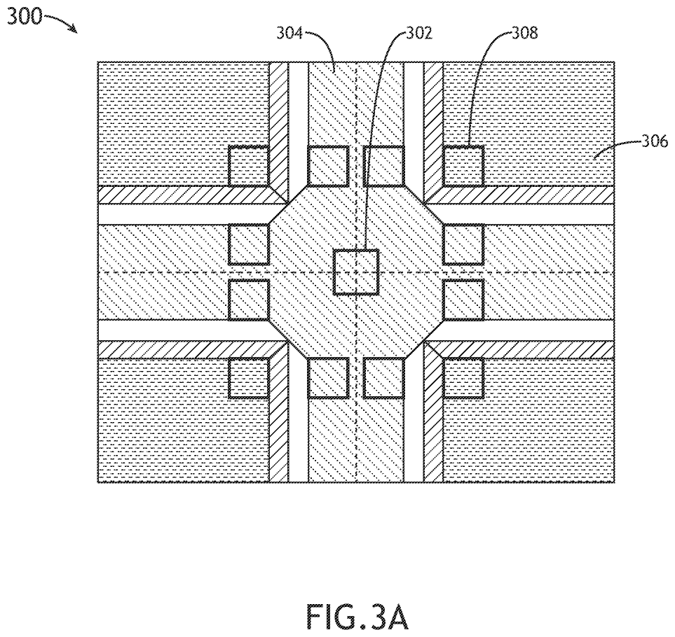

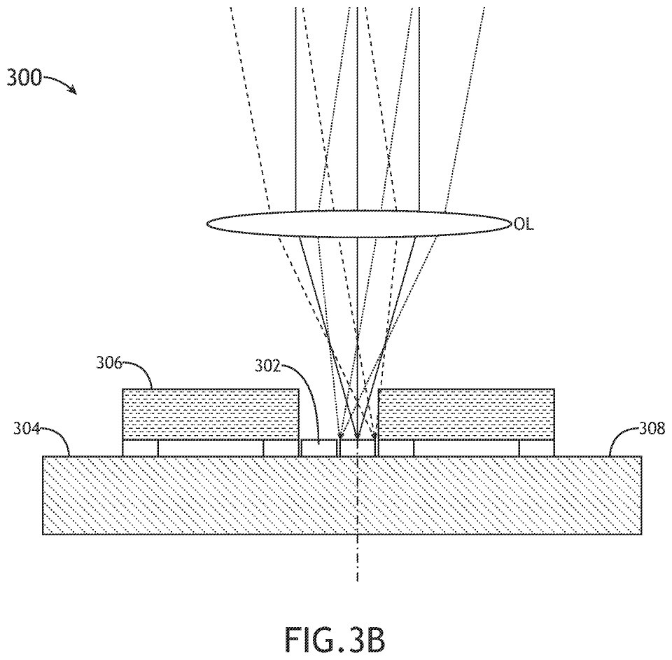

In embodiments, the first set of alignment marks 200 on the wafer 202 are arranged outside a geometric shadow. For example, as shown in FIG. 2B, the first set of alignment marks 200 on the wafer 202 are arranged outside a geometric shadow formed by the second set of alignment marks 204 on the die 206, as discussed further herein. It is contemplated herein portions of the die 206 may prevent light from hitting the first set of alignment marks 200 on the wafer 202 and form a shadow, such that overlay is unable to be measured accurately. For example, as shown in FIG. 2B, the target 104 of the present disclosure may be placed outside the geometric shadow, such that overlay may be measured accurately. In comparison, FIGS. 3A-3B illustrate an overlay target 300. For example, in conventional systems, as shown in FIGS. 3A-3B, the overlay target 300 includes alignment marks 302 on the wafer 304, where walls of a die 306 (including marks 308) may block from hitting the alignment marks 302 on the wafer 304. In this regard, as shown in FIG. 3B, a shadow is generated that prevents accurate overlay measurement.

In embodiments, the second set of alignment marks 204 may be arranged on a corner of the die 206. For example, the second set of alignment marks 204 may be arranged on a corner of the die 206. For instance, the second set of alignment marks 204 on the die 206 may arranged outside a die side shadow 208 and near the die edge 210.

The first set of alignment marks 200 and the second set of alignment marks 204 may be any type and/or shape including, but not limited to, a square (or box), “L” shape, circle, “X” shape, “+” shape, a grating, a bar, or the like.

For example, as shown in FIG. 2A, the first set of alignment marks 200 on the surface of the wafer 202 may be square shaped (or box shaped) and the second set of alignment marks 204 on the surface of the die 206 may be L-shaped. For instance, the first set of alignment marks 200 on the surface of the wafer 202 may include one square mark and the second set of alignment marks 204 on the surface of the die 206 include four L-shaped marks on the corner of the die 206. By way of another example, as shown in FIG. 2C, the first set of alignment marks 200 on the surface of the wafer 202 may be square shaped (or box shaped) and the second set of alignment marks 204 on the surface of the die 206 may be square shaped (or box shaped). For instance, the first set of alignment marks 200 on the surface of the wafer 202 may include two square marks and the second set of alignment marks 204 on the surface of the die 206 include four square marks on the corner of the die 206, where the marks 200, 204 are within a field of view (FOV) 201. In this regard, wafer rotation relative to the detector per site may be calculated.

By way of another, as shown in FIGS. 2D-2G, the first set of alignment marks 200 and the second set of alignment marks 204 may be gratings. In one instance, as shown in FIG. 2D, the first set of alignment marks 200 on the wafer 202 may be grating marks 200 arranged on the surface of the wafer and the second set of alignment mark 204 on the die 206 may be grating marks 204 arranged on the corner of the die 206 within the FOV 201 and illumination spot 203. The grating marks 200, 204 may include a spacing on each grating 200, 204, such that the individual gratings are used to calculate the center of mass at that point. In this regard, the calculated center of mass may be used to calculate the rotation of the target relative to the wafer and correct impacted overlay.

In another instance, as shown in FIGS. 2E-2F, the first set of alignment marks 200 on the wafer 202 may be grating marks 200 arranged on a center surface of the wafer and the second set of alignment mark 204 on the die 206 may be grating marks 204 arranged on the corner of the die 206. Referring to FIG. 2E, the grating marks 200, 204 may include a spacing on each grating 200, 204, such that the individual gratings are used to calculate the center of mass at that point. In this regard, the calculated center of mass may be used to calculate the rotation of the target relative to the wafer and correct impacted overlay.

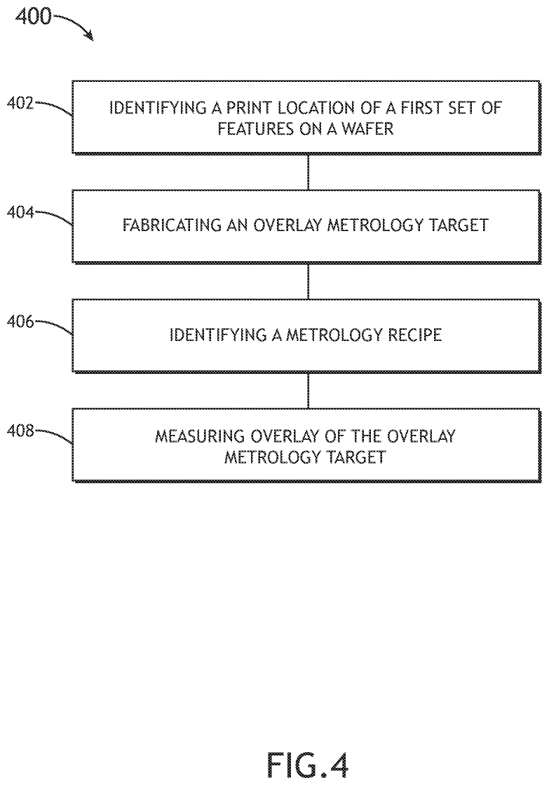

FIG. 4 is a flowchart of a method 400, in accordance with one or more embodiments of the present disclosure. Applicant notes that the embodiments and enabling technologies described previously herein in the context of the control system 100 should be interpreted to extend to method 400. It is further noted, however, that the method 400 is not limited to the architecture of the control system 100.

In a step 402, a printing location of a first set of alignment marks on a wafer may be identified, where the first set of alignment marks are outside a geometric shadow.

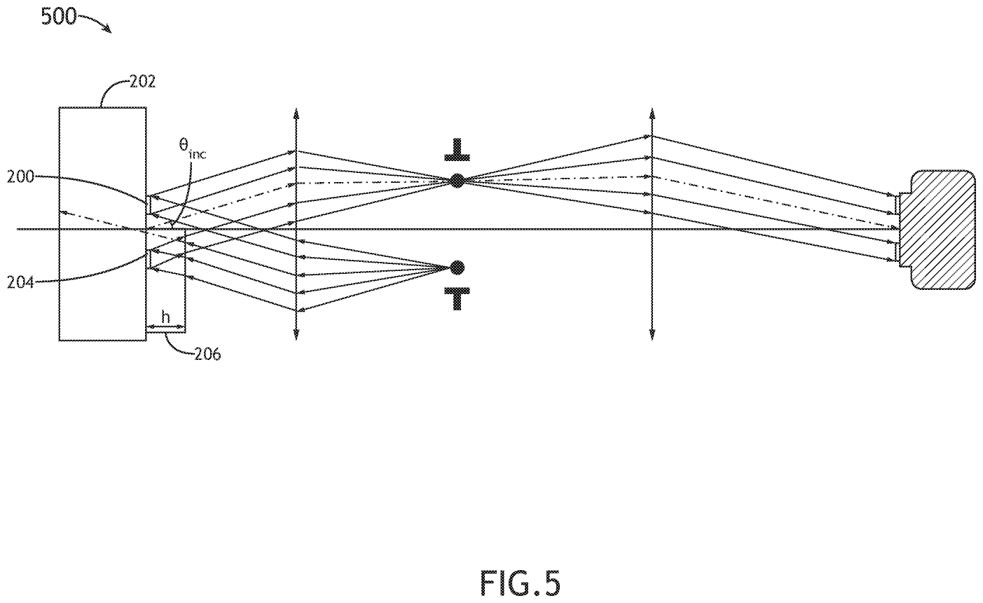

FIG. 5 illustrates a simplified model 500 of die-to-wafer shadowing of the overlay metrology target 104, in accordance with one or more embodiments of the present disclosure.

In embodiments, the geometric shadow may be defined based on at least one of a numerical aperture, die height (or thickness), or die material. For example, the geometric shadow may be defined based on Equations 1.1-1.5, as shown and described below:

$${d}_{air} = h tan {θ}_{inc} \qquad 1.1$$

$${d}_{si} = h tan {θ}_{si} \qquad 1.2$$

$${d}_{air} = h \frac{{NA}_{ill}}{{n}_{air}} \qquad 1.3$$

$${d}_{si} = h \frac{{NA}_{ill}}{{n}_{si}} \qquad 1.4$$

$${df}_{air / si} = h ( \frac{{n}_{si} - 1}{nsi} ) \qquad 1.5$$

where h is die thickness, NAᵢₗₗ is the illumination numerical aperture, nₛᵢ is the refraction index of the die (e.g., 3.5), nₐᵢᵣ is the refraction index of air (e.g., 1), θ_{inc} is the angle of incidence, and dₛᵢ, dₐᵢᵣ is the geometrical shadow.

Referring to FIG. 2G, the target design of the present disclosure may minimize shadowing effects as diffracted rays are aligned with the spacing between the dies, as shown and described by Equation 2 below:

$$sin {θ}_{\pm 1} = \pm ( \frac{λ}{p} + {NA}_{ill} ) \qquad 2$$

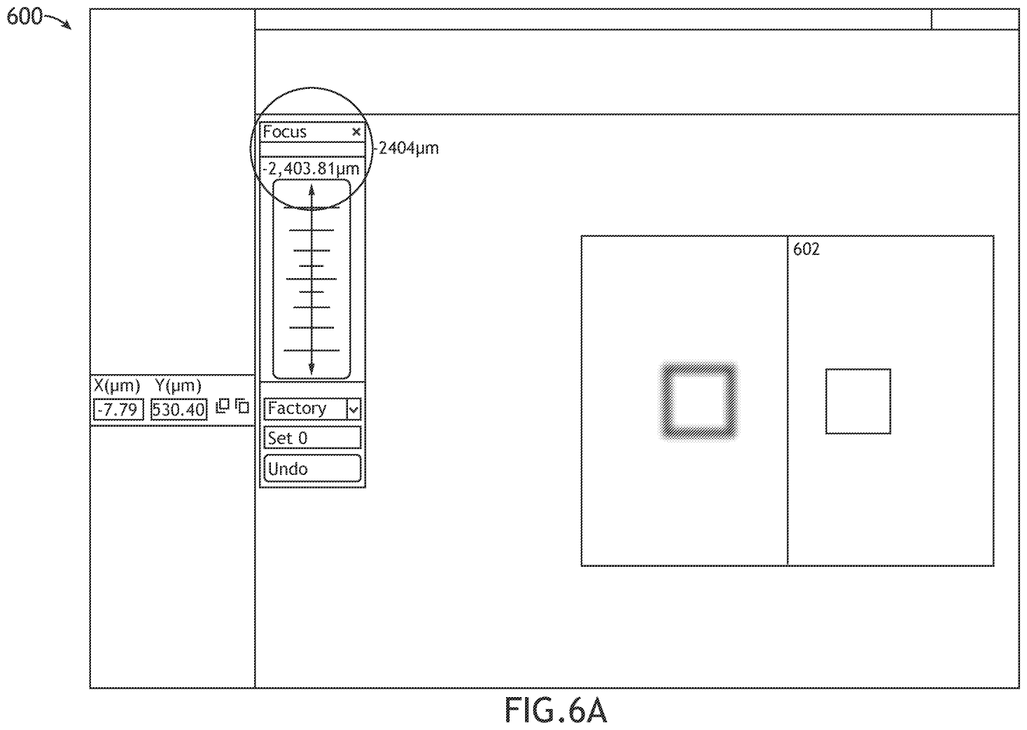

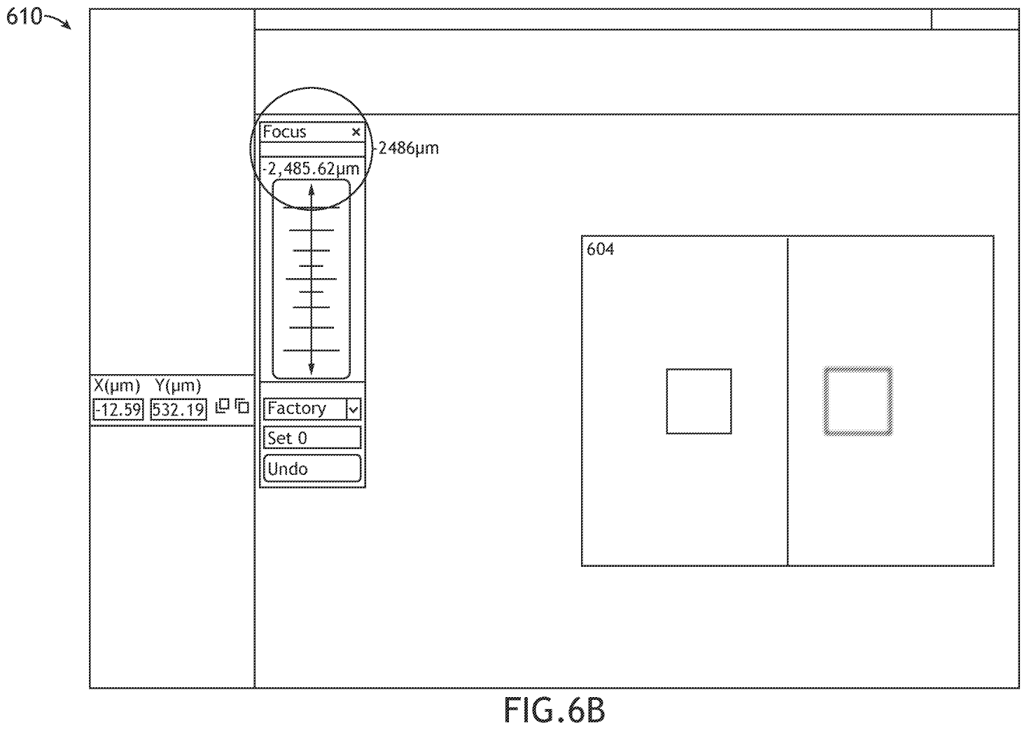

FIGS. 6A-6B illustrate simulation plots 600, 610 depicting die height validation, in accordance with one or more embodiments of the present disclosure. In particular, the simulation plots 600, 610 are generated using a brightfield SWIR microscope with a numerical aperture of 0.2 and a silicon (Si) die-to-wafer sample with approximately 80 μm in thickness.

For example, FIGS. 6A-6B show the z-axis focus stage encoder readout between two focus positions. In one instance, as shown in FIG. 6A, a die top surface 602 is shown where the particles on the top surface 602 are in focus. In another instance, as shown in FIG. 6B, a wafer surface 604 is shown where the overlay alignment mark is in focus. In this regard, the difference between these two positions shown in FIGS. 6A-6B is used to validate the die thickness. For example, the die thickness based on the simulation plots is 82 μm, where the simulation plots 600, 610 were generated using a 80 μm thick die.

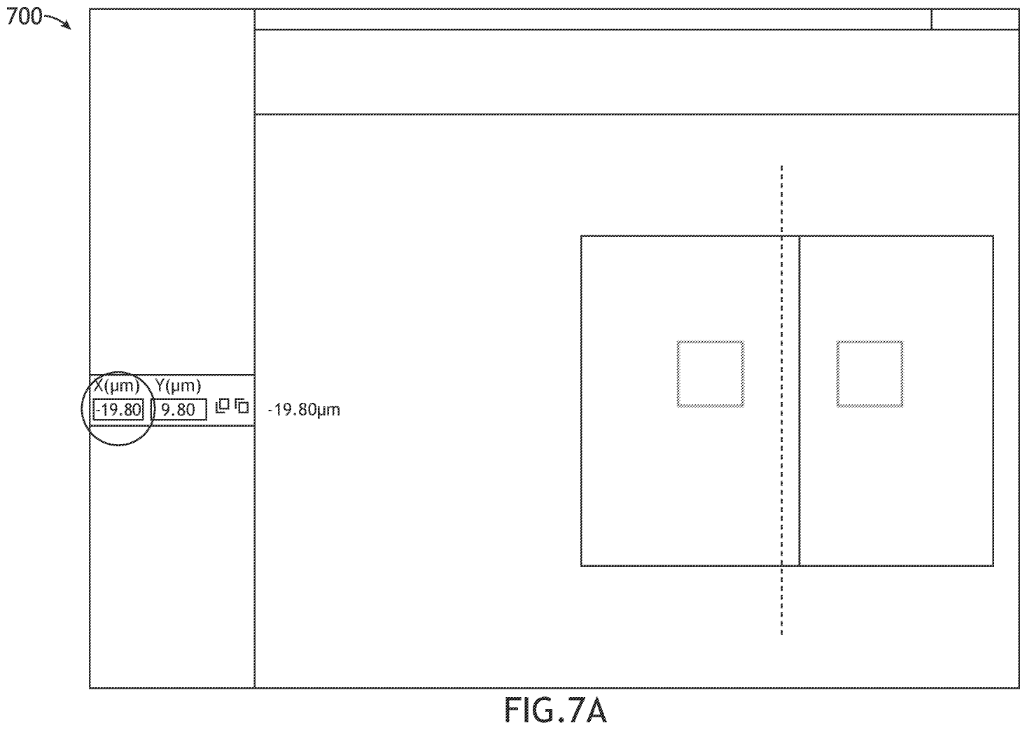

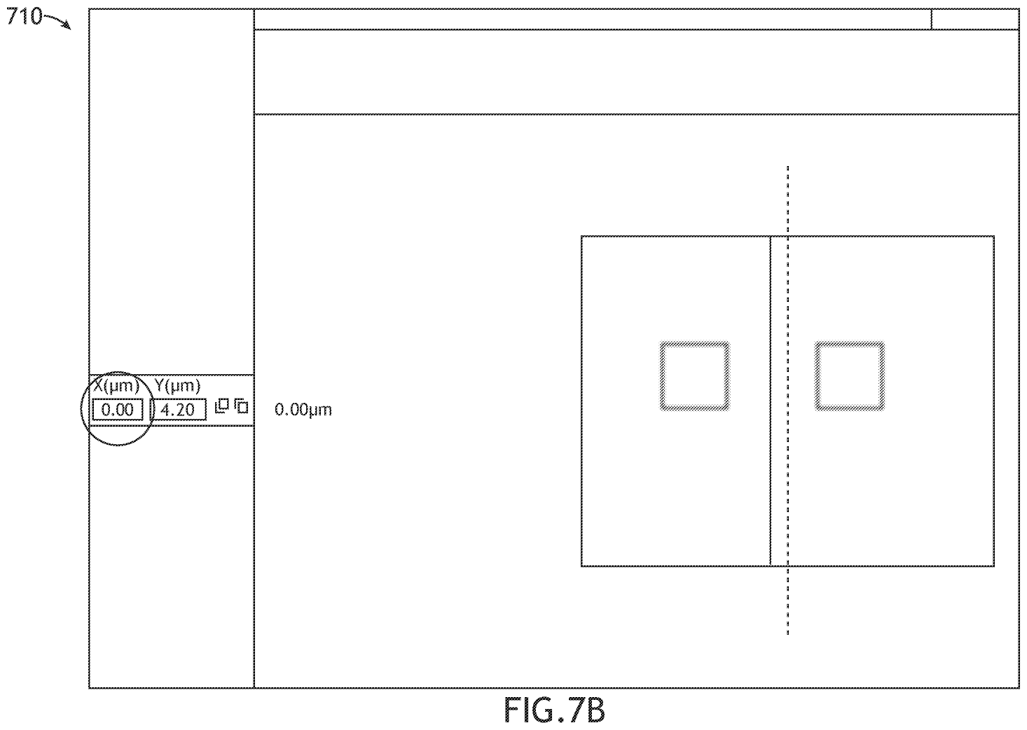

FIGS. 7A-7B illustrate simulation plots 700, 710 depicting die edge shadowing validation, in accordance with one or more embodiments of the present disclosure. In particular, the simulation plots 700, 710 are generated using a brightfield SWIR microscope with a numerical aperture of 0 and a silicon (Si) die-to-wafer sample with approximately 80 μm in thickness, where dₛᵢ=16 μm and dₐᵢᵣ=4.6 μm. As such, the expected overall shadow is 20.6 μm.

For example, simulation plots 700,710 are used to determine the geometric shadow, where the measured geometric shadow is 19.8 μm compared to the expected overall shadow of 20.6 μm.

In a step 404, an overlay metrology target may be fabricated by printing the first set of alignment marks on the wafer based on the identified print location and printing a second set of alignment marks on a surface of the die. It is contemplated that the fabrication sub-system 102 may include any type of fabrication tool suitable for printing an overlay metrology target 104. For example, the fabrication sub-system 102 may include a lithography tool.

In a step 406, a metrology recipe including a set of measurement parameters may be identified. In embodiments, the depth of field (DOF) of the objective must be large enough to allow a single grab high speed measurement of both the wafer mark 200 and the die mark 204.

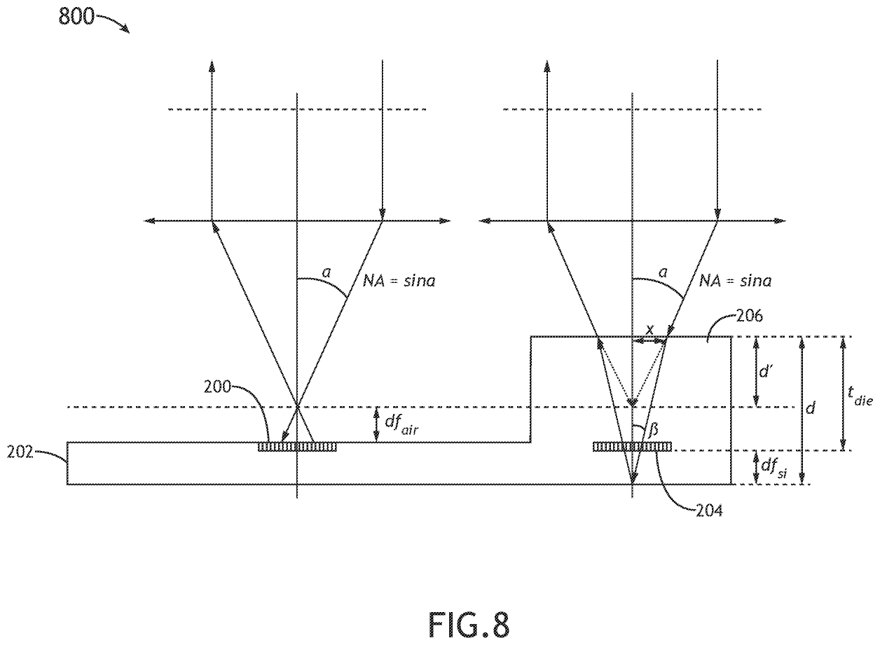

FIG. 8 is a simplified model of a measurement position of an overlay metrology target, in accordance with one or more embodiments of the present disclosure. In particular, FIG. 8 depicts a mutual relationship between wafer side mark and in-die mark. As shown, due to refraction index (n) the die, there is a significant shift between the focal plane of the die and the wafer marks.

In embodiments, the set of measurement parameters may include at least a focal position of an objective lens, where the focal position of the objective lens is a predetermined distance below a top surface of the die. For example, the predetermined distance may be defined by a maximal numerical aperture, as shown and described by Equation 3.1 below:

$$NA = \sqrt{0.6 \frac{0.6 λ}{{t}_{die , Max}} \frac{2 n}{n - 1}} \qquad 3.1$$

where NA is the maximal numerical aperture, λ is wavelength, t_{die,Max} is maximum die thickness, and n is refractive index.

For example, in a non-limiting example where at least 50% contrast is provided, λ is 1.2 μm, t_{die,Max} is 350 μm, n is 3.5, such that the maximal NA is 0.076.

In embodiments, the focus position of the objective lens during measurement may be further defined by the distance from the top surface of the die (d′), as shown and described by Equation 3.2 below:

$${d}^{′} = 0.6 \frac{λ}{{NA}^{2}} \frac{1 + n}{n - 1} \qquad 3.2$$

where d′ is distance below the top surface of the die, NA is the maximal numerical aperture, λ is wavelength, and n is refractive index.

For example, in a non-limiting example, λ is 1.2 μm, NA is 0.076, and n is 3.5, such that d′ is 230.4 μm below the die top surface. In this regard, the focus position of the objective during measurement should be set to 230.4 μm below the die top surface.

It is contemplated herein the dimensions of the die thickness, alignment width, objective lens NA, and wafer dimensions may vary. For example, the die thickness may be between 5 μm and 800 μm. For instance, the die thickness may be between 10 μm and 775 μm. By way of another example, the wafer dimension may be between 10 μm and 100 μm. For instance, the wafer dimension may be between 5 μm and 50 μm. By way of another example, the alignment mark width may be between 1 μm and 10 μm. For instance, the alignment mark width may be between 1 μm and 5 μm. By way of another example, the objective lens NA may be between 0.02 and 0.5. For instance, the objective lens NA may be between 0.05 and 0.25.

In a step 408, overlay of the overlay metrology target including the first set of alignment marks on the surface of the wafer and the second set of alignment marks on the surface of the die may be measured in accordance with the identified metrology recipe.

It is recognized herein that deviations of overlay target alignment marks on a printed layer may thus be representative of deviations of printed characteristics of printed device alignment marks on that layer. Further, overlay measured at one fabrication step (e.g., after the fabrication of one or more sample layers) may be used to generate correctables for precisely aligning a process tool (e.g., a lithography tool, or the like) for the fabrication of an additional sample layer in a subsequent fabrication step.

In embodiments, overlay measurements may be used to monitor and/or control any number of fabrication tools to maintain production of devices according to specified tolerances. For example, overlay measurements of a die layer with respect to a wafer layer on one sample may be utilized as feed-back data to monitor and/or mitigate deviations of the fabrication on additional samples within a lot. By way of another example, overlay measurements of a die layer with respect to a wafer layer on one sample may be utilized as feed-forward data to fabricate a subsequent layer on the same sample in a way that takes into account the existing layer alignments.

Overlay metrology tools may utilize a variety of techniques to determine die-to-wafer overlay. For example, image-based overlay metrology tools may illuminate an overlay target (e.g., an advanced imaging metrology (AIM) target, a box-in-box metrology target, or the like) and capture an overlay signal including an image of overlay target alignment marks located on different die-to-wafer layers. Accordingly, overlay may be determined by measuring the relative positions of the overlay target alignment marks. By way of another example, scatterometry-based overly metrology tools may illuminate an overlay target (e.g., a grating-over-grating metrology target, or the like) and capture an overlay signal including an angular distribution of radiation emanating from the overlay target associated with diffraction, scattering, and/or reflection of the illumination beam. Accordingly, overlay may be determined based on models of the interaction of an illumination beam with the overlay target.

Regardless of the overlay measurement technique, an overlay metrology tool is typically configurable according to a recipe including a set of measurement parameters utilized to generate an overlay signal. For example, a recipe of an overlay metrology tool may include, but is not limited to, an illumination wavelength, a detected wavelength of radiation emanating from the sample, a spot size of illumination on the sample, an angle of incident illumination, a polarization of incident illumination, a position of a beam of incident illumination on an overlay target, a position of an overlay target in the focal volume of the overlay metrology tool, or the like. Accordingly, an overlay recipe may include a set of measurement parameters for generating an overlay signal suitable for determining die-to-wafer overlay.

The accuracy and/or the repeatability of an overlay measurement may depend on the overlay recipe as well as a wide range of factors associated with the particular geometry of the overlay target such as, but not limited to, thicknesses of the die, the sizes of overlay target alignment marks, the density or pitch of overlay target alignment marks, or the composition of sample. Further, the particular geometry of overlay targets may vary across the sample in both predictable and unpredictable manners. For example, the thicknesses of fabricated layers may vary across the sample in a known distribution (e.g., a thickness may be expected to be slightly larger in the center of a sample than along an edge) or may vary according to random fluctuations associated with defects or random variations of processing steps. Accordingly, a particular overlay recipe may not provide the same accuracy and/or repeatability when applied to all overlay targets of a sample, even if process variations are within selected fabrication tolerances.

As used throughout the present disclosure, the term “sample” generally refers to a sample formed of a semiconductor or non-semiconductor material (e.g., a wafer, or the like). For example, a semiconductor or non-semiconductor material may include, but is not limited to, monocrystalline silicon, gallium arsenide, and indium phosphide. A sample may include one or more layers. For example, such layers may include, but are not limited to, a resist, a dielectric material, a conductive material, and a semiconductive material. Many different types of such layers are known in the art, and the term sample as used herein is intended to encompass a sample on which all types of such layers may be formed. One or more layers formed on a sample may be patterned or unpatterned. For example, a sample may include a plurality of dies, each having repeatable patterned alignment marks. Formation and processing of such layers of material may ultimately result in completed devices. Many different types of devices may be formed on a sample, and the term sample as used herein is intended to encompass a sample on which any type of device known in the art is being fabricated. Further, for the purposes of the present disclosure, the term sample and wafer should be interpreted as interchangeable. In addition, for the purposes of the present disclosure, the terms patterning device, mask, and reticle should be interpreted as interchangeable.

Referring to FIG. 1, in embodiments, the metrology sub-system 106 includes an overlay metrology tool 106 to acquire overlay signals from overlay targets based on any number of overlay recipes. For example, the overlay metrology tool may direct illumination to a target 104 and may further collect radiation emanating from the target 104 to generate an overlay signal suitable for the determination of overlay of two or more sample layers. The overlay metrology tool may be any type of overlay metrology tool known in the art suitable for generating overlay signals suitable for determining overlay associated with overlay targets on a target 104. The overlay metrology tool 106 may operate in an imaging mode or a non-imaging mode. For example, in an imaging mode, individual overlay target elements may be resolvable within the illuminated spot on the sample (e.g., as part of a bright-field image, a dark-field image, a phase-contrast image, or the like). By way of another example, the overlay metrology tool 106 may operate as a scatterometry-based overlay metrology tool in which radiation from the sample is analyzed at a pupil plane to characterize the angular distribution of radiation from the target 104 (e.g., associated with scattering and/or diffraction of radiation by the target 104).

Further, the overlay tool may be configurable to generate overlay signals based on any number of recipes defining measurement parameters for the acquiring an overlay signal suitable for determining overlay of an overlay target. For example, a recipe of an overlay metrology tool may include, but is not limited to, an illumination wavelength, a detected wavelength of radiation emanating from the sample, a spot size of illumination on the sample, an angle of incident illumination, a polarization of incident illumination, a position of a beam of incident illumination on an overlay target, a position of an overlay target in the focal volume of the overlay metrology tool, or the like.

In embodiments, the controller 108 is communicatively coupled to the overlay metrology tool 106. The controller 108 may be configured to direct the overlay metrology tool 106 to generate overlay signals based on one or more selected recipes. The controller 108 may be further configured to receive data including, but not limited to, overlay signals from the overlay metrology tool 106. Additionally, the controller 108 may be configured to determine overlay associated with an overlay target based on the acquired overlay signals.

In embodiments, the controller 108 includes one or more processors 110. For example, the one or more processors 110 may be configured to execute a set of program instructions maintained in a memory device 112, or memory. The one or more processors 110 of a controller 108 may include any processing element known in the art. In this sense, the one or more processors 110 may include any microprocessor-type device configured to execute algorithms and/or instructions. Further, the memory device 112 may include any storage medium known in the art suitable for storing program instructions executable by the associated one or more processors 110. For example, the memory device 112 may include a non-transitory memory medium. As an additional example, the memory device 112 may include, but is not limited to, a read-only memory, a random-access memory, a magnetic or optical memory device (e.g., disk), a magnetic tape, a solid state drive and the like. It is further noted that memory device 112 may be housed in a common controller housing with the one or more processors 110.

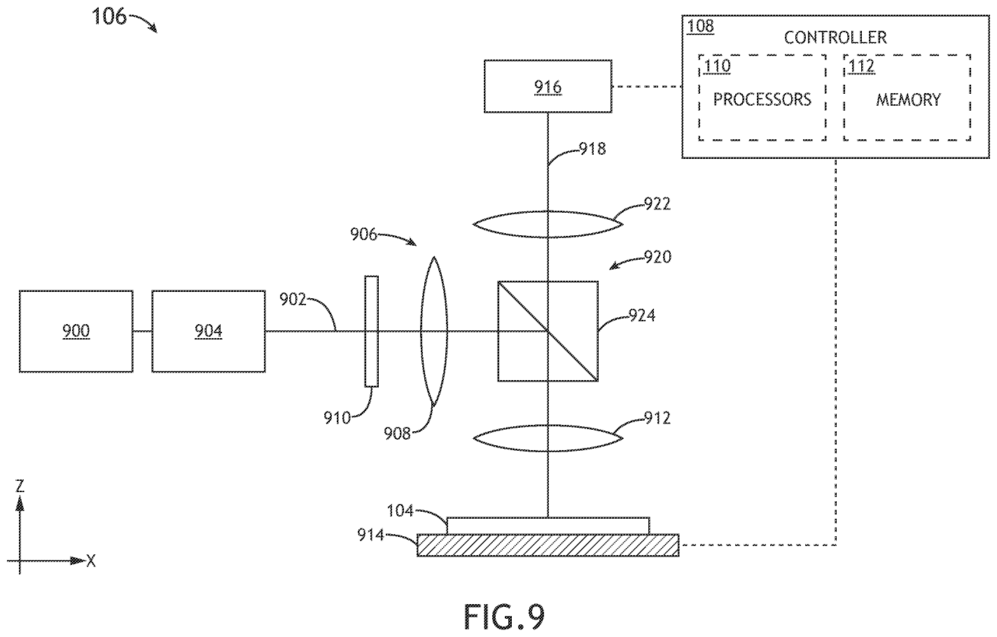

FIG. 9 is a conceptual view illustrating the overlay metrology tool 106, in accordance with one or more embodiments of the present disclosure. In one embodiment, the overlay metrology tool 106 includes an illumination source 900 configured to generate an illumination beam 902. The illumination beam 902 may include one or more selected wavelengths of light including, but not limited to, ultraviolet (UV) radiation, visible radiation, or infrared (IR) radiation.

The illumination source 900 may include any type of illumination source suitable for providing an illumination beam 902. In embodiments, the illumination source 900 is a laser source. For example, the illumination source 900 may include, but is not limited to, one or more narrowband laser sources, a broadband laser source, a supercontinuum laser source, a white light laser source, or the like. In this regard, the illumination source 900 may provide an illumination beam 902 having high coherence (e.g., high spatial coherence and/or temporal coherence). In another embodiment, the illumination source 900 includes a laser-sustained plasma (LSP) source. For example, the illumination source 900 may include, but is not limited to, a LSP lamp, a LSP bulb, or a LSP chamber suitable for containing one or more elements that, when excited by a laser source into a plasma state, may emit broadband illumination. In embodiments, the illumination source 900 includes a lamp source. For example, the illumination source 900 may include, but is not limited to, an arc lamp, a discharge lamp, an electrode-less lamp, or the like. In this regard, the illumination source 900 may provide an illumination beam 902 having low coherence (e.g., low spatial coherence and/or temporal coherence).

In embodiments, the overlay metrology tool 106 includes a wavelength selection device 904 to control the spectrum of the illumination beam 902 for illumination of the target 104. For example, the wavelength selection device 904 may include a tunable filter suitable for providing an illumination beam 902 with a selected spectrum (e.g., center wavelength, bandwidth, spectral profile, or the like). By way of another example, the wavelength selection device 904 may adjust one or more control settings of a tunable illumination source 900 to directly control the spectrum of the illumination beam 902. Further, the controller 108 may be communicatively coupled to the illumination source 900 and/or the wavelength selection device 904 to adjust one or more aspects of the spectrum of the illumination beam 902.

In embodiments, the overlay metrology tool 106 directs the illumination beam 902 to the target 104 via an illumination pathway 906. The illumination pathway 906 may include one or more optical components suitable for modifying and/or conditioning the illumination beam 902 as well as directing the illumination beam 902 to the target 104. For example, the illumination pathway 906 may include, but is not required to include, one or more lenses 908 (e.g., to collimate the illumination beam 902, to relay pupil and/or field planes, or the like), one or more polarizers 910 to adjust the polarization of the illumination beam 902, one or more filters, one or more beam splitters, one or more diffusers, one or more homogenizers, one or more apodizers, one or more beam shapers, or one or more mirrors (e.g., static mirrors, translatable mirrors, scanning mirrors, or the like). In embodiments, the overlay metrology tool 106 includes an objective lens 912 to focus the illumination beam 902 onto the target 104 (e.g., an overlay target with overlay target elements located on two or more layers of the target 104).

In embodiments, the target 104 is disposed on a sample stage 914 suitable for securing the target 104 and further configured to position the target 104 with respect to the illumination beam 902.

In embodiments, the overlay metrology tool 106 includes one or more detectors 916 configured to capture radiation emanating from the target 104 (e.g., an overlay target on the target 104) (e.g., sample radiation 918) through a collection pathway 920 and generate one or more overlay signals indicative of overlay of two or more layers of the target 104. The collection pathway 920 may include multiple optical elements to direct and/or modify illumination collected by the objective lens 912 including, but not limited to one or more lenses 922, one or more filters, one or more polarizers, one or more beam blocks, or one or more beamsplitters. For example, a detector 916 may receive an image of the target 104 provided by elements in the collection pathway 920 (e.g., the objective lens 912, the one or more lenses 922, or the like). By way of another example, a detector 916 may receive radiation reflected or scattered (e.g., via specular reflection, diffuse reflection, and the like) from the target 104. By way of another example, a detector 916 may receive radiation generated by the sample (e.g., luminescence associated with absorption of the illumination beam 902, and the like). By way of another example, a detector 916 may receive one or more diffracted orders of radiation from the target 104 (e.g., 0-order diffraction, 1 order diffraction, 2 order diffraction, and the like).

The detector 916 may include any type of optical detector known in the art suitable for measuring illumination received from the target 104. For example, the detector 916 may include, but is not limited to, a charge-coupled device (CCD) detector, a time-delay integration (TDI) detector, a photomultiplier tube (PMT), an avalanche photodiode (APD), a complementary metal-oxide-semiconductor (CMOS) sensor, or the like. In embodiments, the detector 916 may include a spectroscopic detector suitable for identifying wavelengths of light emanating from the target 104.

The illumination pathway 906 and the collection pathway 920 of the overlay metrology tool 106 may be oriented in a wide range of configurations suitable for illuminating the target 104 with the illumination beam 902 and collecting radiation emanating from the target 104 in response to the incident illumination beam 902. For example, as illustrated in FIG. 9, the overlay metrology tool 106 may include a beamsplitter 924 oriented such that the objective lens 912 may simultaneously direct the illumination beam 902 to the target 104 and collect radiation emanating from the target 104. By way of another example, the illumination pathway 906 and the collection pathway 920 may contain non-overlapping optical paths.

As described previously herein, the overlay metrology tool 106 may be configurable to generate overlay signals associated with overlay marks on the target 104 using any number of overlay recipes (e.g., sets of measurement parameters). Further, the overlay metrology tool 106 may provide rapid tuning of the measurement parameters such that multiple overlay signals based on different recipes may be rapidly acquired. For example, the controller 108 of the overlay metrology tool 106 may be communicatively coupled with one or more adjustable components of the overlay metrology tool 106 to configure the adjustable components in accordance with an overlay recipe.

An overlay recipe may include one or more aspects of the spectrum of the illumination beam 902 incident on the sample such as, but not limited to the wavelength (e.g., the central wavelength), the bandwidth, and the spectral profile of the illumination beam 902 as measurement parameters. For example, the controller 108 may be communicatively coupled to the illumination source 900 and/or the wavelength selection device 904 to adjust the spectrum of the illumination beam 902 in accordance with an overlay recipe.

In embodiments, the wavelength selection device 904 includes one or more position-tunable spectral filters in which spectral characteristics of an incident illumination beam 902 (e.g., a center wavelength, a bandwidth, a spectral transmissivity value or the like) may be rapidly tuned by modifying the position of the illumination beam 902 on the filter. Further, position-tunable spectral filters may include any type of spectral filter such as, but not limited to, a low-pass filter, a high-pass filter, a band-pass filter, or a band-reject filter.

For example, a position-tunable spectral filter may include one or more thin films operating as an edge filter with a position-tunable cutoff wavelength. In this regard, the cutoff wavelength may be tuned by modifying the position of the illumination beam 902 on the filter. For instance, a low-pass edge filter may pass (e.g., via transmission or reflection) wavelengths below the cutoff wavelength, whereas a high-pass edge filter may pass wavelengths above the cutoff wavelength. Further, a band-pass filter may be formed from a low-pass edge filter combined with a high-pass edge filter.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” “temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A method comprising:
identifying a printing location of a first set of alignment marks on a wafer, wherein the first set of alignment marks are outside a geometric shadow defined by a numerical aperture and a die height of a die;
fabricating an overlay metrology target by printing the first set of alignment marks on the wafer based on the identified print location and printing a second set of alignment marks on a surface of the die;
identifying a metrology recipe including a set of measurement parameters, wherein the set of measurement parameters include at least a focal position of an objective lens, wherein the focal position of the objective lens is a predetermined distance below a top surface of the die, wherein the predetermined distance is defined by a maximal numerical aperture and the die height of the die; and
measuring overlay of the overlay metrology target including the first set of alignment marks on the surface of the wafer and the second set of alignment marks on the surface of the die in accordance with the identified metrology recipe.

2. The method of claim 1, wherein the overlay metrology target is fabricated using a lithography sub-system, wherein the lithography sub-system prints the first set of alignment marks on the wafer based on the identified print location and prints the second set of alignment marks on the surface of the die.

3. The method of claim 1, wherein overlay of the overlay metrology target is measured using an overlay metrology sub-system based on the first set of alignment marks on the surface of the wafer and the second set of alignment marks on the surface of the die in accordance with the identified metrology recipe.

4. The method of claim 3, wherein the first set of alignment marks arranged on the surface of the wafer and the second set of alignment marks arranged on the surface of the die are simultaneously measured using the overlay metrology sub-system.

5. The method of claim 1, wherein the second set of alignment marks are printed on a die corner on the surface of the die.

6. The method of claim 1, wherein the first set of alignment marks on the wafer are square alignment marks.

7. The method of claim 1, wherein the second set of alignment marks on the die are L-shaped alignment marks.

8. The method of claim 1, wherein the first set of alignment marks on the wafer are grating marks.

9. The method of claim 1, wherein the second set of alignment marks on the die are grating marks.

10. An overlay metrology target comprising:
a first set of alignment marks arranged on a surface of a wafer; and
a second set of alignment marks arranged on a surface of a die,
wherein the first set of alignment marks arranged on the wafer are outside a geometric shadow defined by a numerical aperture and a height of the second set of alignment marks arranged on the surface of the die.

11. The overlay metrology target of claim 10, wherein the second set of alignment marks are arranged on a die corner on the surface of the die.

12. The overlay metrology target of claim 10, wherein the first set of alignment marks on the wafer are square alignment marks.

13. The overlay metrology target of claim 10, wherein the second set of alignment marks on the die are L-shaped alignment marks.

14. The overlay metrology target of claim 10, wherein the first set of alignment marks on the wafer are grating marks.

15. The overlay metrology target of claim 10, wherein the second set of alignment marks on the die are grating marks.

16. The overlay metrology target of claim 10, wherein the first set of alignment marks arranged on the surface of the wafer and the second set of alignment marks arranged on the surface of the die are simultaneously measured using an overlay metrology sub-system.

17. A control system comprising:
a controller configured to be communicatively coupled with an overlay metrology sub-system and a fabrication sub-system, the controller including one or more processors configured to execute program instructions causing the one or more processors to:
identify a printing location of a first set of alignment marks on a wafer, wherein the first set of alignment marks are outside a geometric shadow defined by a numerical aperture and a die height of a die;
provide the identified printing location to the fabrication sub-system to fabricate an overlay metrology target by printing the first set of alignment marks on the wafer based on the identified print location and printing a second set of alignment marks on a surface of the die;
determine a metrology recipe including a set of measurement parameters, wherein the set of measurement parameters include at least a focal position of an objective lens, wherein the focal position of the objective lens is a predetermined distance below a top surface of the die, wherein the predetermined distance is defined by a maximal numerical aperture and the die height of the die; and
provide the determined metrology recipe to the overlay metrology sub-system to measure overlay of the overlay metrology target including the first set of alignment marks on the surface of the wafer and the second set of alignment marks on the surface of the die in accordance with the identified metrology recipe.

18. The control system of claim 17, wherein the fabrication sub-system comprises a lithography sub-system.

19. The control system of claim 17, wherein the first set of alignment marks arranged on the surface of the wafer and the second set of alignment marks arranged on the surface of the die are simultaneously measured using the overlay metrology sub-system.

20. The control system of claim 17, wherein the second set of alignment marks are printed on a die corner on the surface of the die.

21. The control system of claim 17, wherein the first set of alignment marks on the wafer are square alignment marks, wherein the second set of alignment marks on the die are L-shaped alignment marks.

22. The control system of claim 17, wherein the first set of alignment marks on the wafer are grating marks, wherein the second set of alignment marks on the die are additional grating marks.
